(19) United States
(12) Patent Application Publication
(10) Pub. No.: US 2025/0133652 A1
(43) Pub. Date: Apr. 24, 2025

(54) PRINTED CIRCUIT BOARD ASSEMBLY

(71) Applicant: Cisco Technology, Inc., San Jose, CA (US)

(72) Inventors: Yuqing Zhu, Shanghai (CN); Wenbin Ma, Shanghai (CN); Mike Sapozhnikov, San Jose, CA (US); Weiying Ding, Shanghai (CN); Mingjian Gao, Shanghai (CN); Mingtong Zuo, Shanghai (CN); David Nozadze, San Jose, CA (US); Joel Richard Goergen, Soulsbyville, CA (US)

(21) Appl. No.: 18/532,182

(22) Filed: Dec. 7, 2023

Related U.S. Application Data
(60) Provisional application No. 63/591,822, filed on Oct. 20, 2023.

(51) Int. Cl. H05K 1/02; H01L 21/48; H01L 23/498; H05K 3/40

(52) U.S. Cl. CPC H05K 1/0222; H01L 21/486; H01L 23/49827; H01L 23/49838; H05K 3/4038; H05K 2201/09481; H05K 2201/096; H05K 2201/09609; H05K 2201/09636

(57) ABSTRACT

In some embodiments, an apparatus includes a layer of a printed circuit board (PCB), a pair of signal vias formed on the layer of the PCB and including a first signal via a second signal via each configured to propagate a respective signal, a first plurality of ground vias formed on the layer and at least partially circumferentially surrounding the first signal via of the pair of signal vias, and a second plurality of ground vias formed on the layer and at least partially circumferentially surrounding the second signal via of the pair of signal vias. The first plurality of ground vias and the second plurality of ground vias include a shared ground via.

### CROSS-REFERENCE TO RELATED APPLICATION

This application claims priority to and the benefit of U.S. Provisional Application No. 63/591,822, entitled “PRINTED CIRCUIT BOARD ASSEMBLY,” filed Oct. 20, 2023, which is hereby incorporated by reference in its entirety for all purposes.

### TECHNICAL FIELD

The present disclosure relates to a printed circuit board (PCB).

### BACKGROUND

A printed circuit board (PCB) electrically couples various electronic components with one another. For example, a PCB may include multiple layers, each having different electronic components and traces routed along the layers to electrically couple to electronic components of the same layer. Additionally, the PCB may include vias that extend between layers to electrically couple electronic components of different layers to one another. For example, a signal may propagate from a first electronic component of a first layer, through a first trace routed along the first layer, through a via extending from the first layer to a second layer, through a second trace routed along the second layer, and to a second electronic component of the second layer. Unfortunately, electric fields of vias may overlap with one another to cause crosstalk in which signals propagating along the vias interfere with one another, especially for signals transmitted at higher data rates. As a result, the integrity of signals may be reduced, and operation of the PCB (e.g., of electronic components configured to transmit/receive signals) may be undesirable.

### BRIEF DESCRIPTION OF THE DRAWINGS

FIG. 1 is a perspective cross-sectional view of a printed circuit board (PCB) coupled to an integrated circuit (IC), according to an example embodiment.

FIG. 2 is a side view of the PCB of FIG. 1, according to an example embodiment.

FIG. 3 is a schematic diagram of an outer layer of a PCB, according to an example embodiment.

FIG. 4 is a schematic diagram of an intermediate layer of a PCB, according to an example embodiment.

FIG. 5 is a schematic diagram of an intermediate layer of a PCB, according to another example embodiment.

FIG. 6 is a schematic diagram of vias at an intermediate layer of a PCB, according to an example embodiment.

FIG. 7 is a schematic diagram of vias at an intermediate layer of a PCB, according to another example embodiment.

FIG. 8 is a schematic diagram illustrating electric fields emitted by vias of a PCB, according to an example embodiment.

FIG. 9 is another side view of the PCB of FIG. 1, according to an example embodiment.

FIG. 10 is a schematic diagram of an intermediate layer of a PCB, according to an example embodiment.

FIG. 11 is a flowchart of a method of manufacturing a PCB, according to an example embodiment.

### DETAILED DESCRIPTION

### Overview

The present disclosure is directed to a printed circuit board (PCB). In some aspects, the techniques described herein relate to an apparatus including: a layer of a printed circuit board (PCB); a pair of signal vias formed on the layer of the PCB, wherein the pair of signal vias includes a first signal via and a second signal via, each of which is configured to propagate a respective signal; a first plurality of ground vias formed on the layer and at least partially circumferentially surrounding the first signal via of the pair of signal vias; and a second plurality of ground vias formed on the layer and at least partially circumferentially surrounding the second signal via of the pair of signal vias, wherein the first plurality of ground vias and the second plurality of ground vias include a shared ground via.

### Example Embodiments

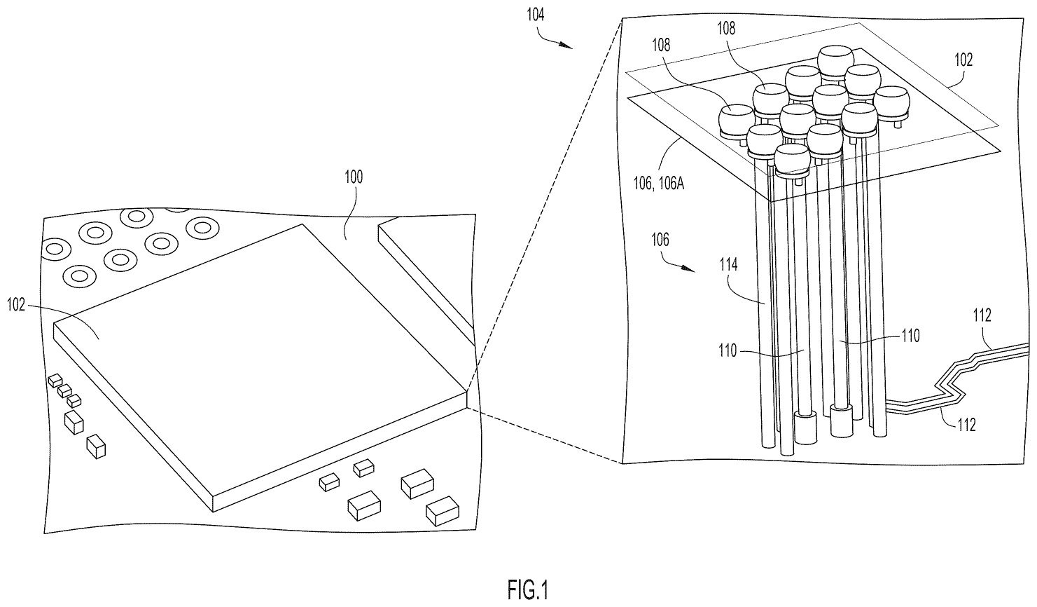

With reference made to FIG. 1, depicted therein is a PCB 100 with an integrated circuit (IC) 102 coupled thereto. For example, the PCB 100 electrically couples the IC 102 to another component, such as another IC, to enable communication between the IC 102 and the other component. View 104 shows a cross-section of the PCB 100 to illustrate additional details of the PCB 100 related to coupling to the IC 102.

As shown in view 104, the PCB 100 includes multiple layers 106. For instance, the PCB 100 may include an outer layer 106A, as well as one or more intermediate layers (not shown). Pads, balls, or pins 108 are formed on the outer layer 106A, and the IC 102 is configured to couple to the pads 108, such as using a soldering technique, to couple to the PCB 100. In this manner, the outer layer 106A may position the pads 108 to be exposed and accessible for coupling the IC 102 thereto. Additionally, signal vias 110 (e.g., multiple pairs of signal vias 110) are formed through the intermediate layers and are configured to propagate respective signals, such as to enable communication of signals from the IC 102 and/or toward the IC 102. For example, a signal via 110 is a part of a differential pair configured to propagate corresponding signals (e.g., a positive signal, a negative signal). A signal via 110 may alternatively be configured to propagate a signal that is separate from and unrelated to any other signal. In some embodiments, the signal vias 110 terminate prior to the outer layer 106A. That is, the signal vias 110 are not formed through the outer layer 106A. In such embodiments, the PCB 100 may include microvias to couple the signal vias 110 to corresponding pads 108 to communicatively couple the IC 102 to the signal vias 110 by way of the pads 108. Additionally or alternatively, the signal vias 110 are formed through the outer layer 106A and are directly coupled to corresponding pads 108. In either case, the signal vias 110 may include plated through hole (PTH) (e.g., partial PTH) vias that extend through each of the intermediate layers of the PCB 100.

Respective traces 112 are coupled to the signal vias 110 at one of the intermediate layers and are configured to propagate signals, such as between the signal vias 110 (e.g., and therefore the IC 102 communicatively coupled to the signal vias 110) and another component or another signal via 110. The traces 112 are routed along the intermediate layer. In this manner, the signal vias 110 extending through multiple intermediate layers may be communicatively coupled to components of different layers (e.g., the IC 102 near the outer layer 106A, an electronic component at an intermediate layer), and the traces 112 may communicatively couple the signal vias 110 to a component at a particular layer, such as a particular intermediate layer.

Ground or stitching vias 114 are also formed through the layers 106. For example, each ground via 114 may be a PTH (e.g., a partial PTH) extending through the intermediate layers. The ground vias 114 help maintain desirable integrity of the signals propagated by the signal vias 110. For instance, during operation in which the signal vias 110 transmit signals, electric fields may be emitted from the signal vias 110 and/or from the pads 108 coupled to the signal vias 110. The ground vias 114 help reduce or prevent leakage of the electric fields to other signal vias 110, which may otherwise interfere with (e.g., reduce an integrity of) signals propagated along the other signal vias 110. In other words, the ground vias 114 help isolate the electric fields of the signal vias 110, which may reduce overall signal loss associated with the PCB 100, thereby improving performance related to signal transmission.

The traces 112 may be routed to avoid contact with the ground vias 114 to facilitate functionality of the ground vias 114. For instance, the traces 112 are arranged to be offset from the ground vias 114 by a particular distance to avoid signal transmission onto the ground vias 114, thereby enabling the ground vias 114 to reduce electric field leakage. As discussed herein, the ground vias 114 may be positioned in a particular arrangement relative to the signal vias 110 to reduce electric field leakage and enable desirable routing of the traces 112 along a layer.

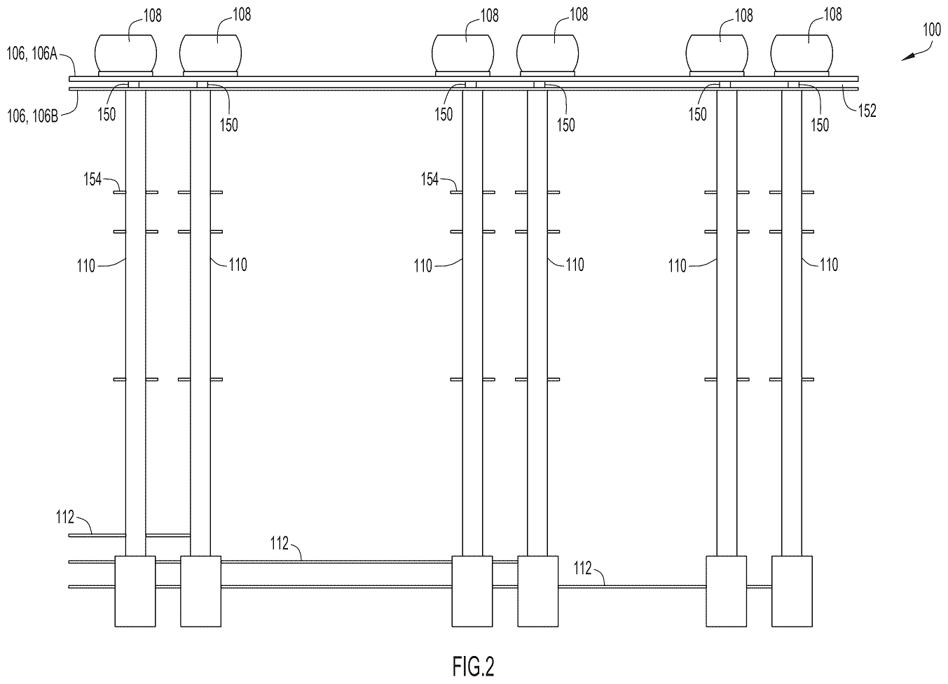

FIG. 2 is a side cross-sectional view of the PCB 100 having multiple pairs of signal vias 110. Certain components (e.g., ground vias) are not illustrated for visualization purposes. Each signal via 110 is formed through intermediate layers of the PCB 100, such as an intermediate layer 106B that is one of a plurality of intermediate layers (e.g., with any suitable quantity, such as over 40, intermediate layers). The intermediate layer 106B is immediately adjacent to the outer layer 106A. Thus, the intermediate layer 106B may be considered an outermost intermediate layer of the intermediate layers. Each signal via 110 may terminate at the intermediate layer 106B and therefore does not extend to the outer layer 106A or to the pads 108 at the outer layer 106A. Accordingly, the signal vias 110 may not be directly in contact with the pads 108. For this reason, signal microvias 150 are used to communicatively couple the signal vias 110 to corresponding pads 108. Each signal microvia 150 extends between the outer layer 106A and the intermediate layer 106B to couple to a corresponding pad 108 and a corresponding signal via 110. The arrangement of the signal microvias 150 provides a high density interconnect (HDI) 152 between the outer layer 106A and the intermediate layer 106B.

The HDI 152 may help isolate the signals transmitted along the signal vias 110 at the intermediate layers from the signals transmitted to and/or from the IC 102 by limiting direct contact between components of the outer layer 106A and components of the intermediately layers. That is, the HDI 152 may help isolate the signal vias 110 and connectors (e.g., a ball pin field) of the IC 102 from one another. Such signal isolation may further help maintain desirable signal integrity, especially for implementations in which the intermediate layers include power planes that may be associated with relatively increased electric fields. For instance, the HDI 152 may reduce electric field leakage between the IC 102 and the signal vias 110 to reduce signal loss.

Respective traces 112 are coupled to the signal vias 110 at different intermediate layers (e.g., to provide breakout layers of the intermediate layers). For example, the traces 112 coupled to different pairs of signal vias 110 are routed along different intermediate layers. Thus, the traces 112 may communicatively couple respective pairs of signal vias 110 to different components located at different intermediate layers. Additionally, one or more capacitive structures 154 may be attached to each signal via 110. The capacitive structures 154 may adjust a capacitance related to the signal vias 110 to improve signal propagation along the signal vias 110, such as to tune a corresponding impedance and provide more homogenous impedance levels along the signal vias 110 to reduce signal loss.

In some embodiments, the area surrounding the intermediate layers between the outer layers may generally remain open. The open environment around the intermediate layers may further facilitate operation of the PCB 100. For example, signal transmission (e.g., high current power delivery) may generate heat, which may be readily discharged to the surrounding openings. Thus, thermal dissipation may be improved to enable the PCB 100 to operate desirably.

Although FIG. 2 illustrates a single HDI 152, it should be noted that the PCB 100 may include an additional HDI 152. For example, the PCB 100 may have a belly-to-belly configuration in which components are coupled to opposite sides of the PCB 100. To this end, the PCB 100 may include outer layers at the opposite sides, as well as respective outermost intermediate layers immediately adjacent to the outer layers (e.g., the signal vias 110 may extend from one outermost intermediate layer to an opposite outermost intermediate layer). A separate HDI 152 may be formed between each outer layer and its corresponding outermost intermediate layer.

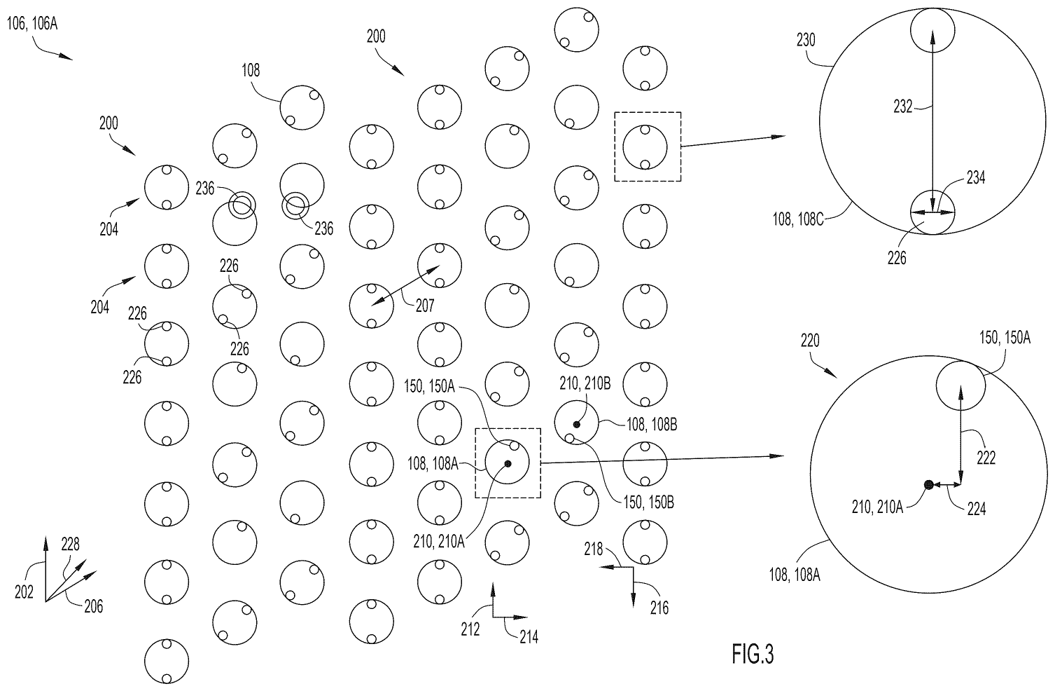

FIG. 3 is a schematic diagram of the outer layer 106A of the PCB 100. For example, the outer layer 106A may include a topmost layer and/or a bottommost layer of the PCB 100 (e.g., the outer layer 106A may represent both the topmost layer and the bottommost layer in a belly-to-belly configuration). Each pad 108 includes a circular shape and may have a diameter of between 0.4 millimeters (mm) and 0.6 mm (between 0.01575 inches (in) or 15.75 mil and 0.0236 in or 23.6 mil). The illustrated pads 108 are arranged on the outer layer 106A to form a plurality of columns 200 extending along a first axis 202, as well as a plurality of rows 204 extending along a second axis 206 that is oriented obliquely (e.g., at a 60 degree angle) relative to the first axis 202. In certain embodiments, such an arrangement of the pads 108 is limited by a manufacturing technique or operation and may not be easily adjustable (e.g., to change the spacing between pads 108, to change the extension of the rows 204 relative to the columns 200). In other words, different outer layers 106A (e.g., of different PCBs) may each have the depicted arrangement of the pads 108. For example, the pads 108 may be positioned such that a pitch 207 of between 0.8 mm and 1 mm (e.g., between 0.0315 in or 31.5 mil and 0.0394 in or 39.4 mil) extends between centers of adjacent pads 108 (e.g., along the first axis 202, along the second axis 206). The arrangement of the pads 108 defines a ball grid array or pin field that may be used to couple to the IC 102. Moreover, some of the pads 108 may be used for coupling to the signal vias 110 (e.g., to communicatively couple the IC 102 to the signal vias 110), and a remainder of the pads 108 may be used for ground to help isolate electric fields.

For example, a pair of signal microvias 150 may be coupled to (e.g., directly in contact with) a corresponding pair of pads 108 that are immediately adjacent to one another along a common row 204. The signal microvias 150 are attached to the corresponding pads 108 at locations that are offset from the centers of the pads 108 to position the signal microvias 150 more proximate to one another. To this end, for each pair of signal microvias 150, a first signal microvia 150A coupled to a first pad 108A is positioned offset from a first center 210A in a first direction 212 (e.g., extending along the axis 202) and in a second direction 214 perpendicular to the first direction 212. A second signal microvia 150B of each pair of signal microvias 150 is coupled to a second pad 108B and is positioned offset from a second center 210B in the opposite manner. That is, the second signal microvia 150B is offset from the second center 210B in a third direction 216, opposite the first direction 212, and in a fourth direction 218, opposite the second direction 214. In this way, the signal microvias 150 are offset from the respective centers 210 in directions toward one another to position the signal microvias 150 more proximate to one another.

Detailed view 220 of the first layer 106A illustrates positioning of the first signal microvia 150A relative to the first center 210A of the first pad 108A. In particular, the first signal microvia 150A is offset from the first center 210A in the first direction 212 to form a first dimension 222 extending between the first center 210A and the first signal microvia 150A in the first direction 212. Additionally, the first signal microvia 150A is offset from the first center 210A in the second direction 214 to form a second dimension 224 extending between the first center 210A and the first signal microvia 150A in the second direction 214. As an example, the first dimension 222 is between 0.18 mm and 0.2 mm (between 0.007 in or 7 mil and 0.00787 in or 7.87 mil) and the second dimension 224 is between 0.06 mm and 0.08 mm (between 0.00236 in or 2.36 mil and 0.00315 in or 3.15 mil). The second signal microvia 150B may be similarly offset from the second center 210B in the opposite manner (e.g., the positionings of the signal microvias 150 on the respective pads 108 mirror one another). In additional or alternative embodiments, the microvias 150 may be positioned in any suitable manner relative to the respective pads 108, such as in a non-mirroring configuration.

Each signal microvia 150 is coupled to (e.g., directly in contact with) one of the signal vias 110, thereby coupling the corresponding pad 108 to the signal via 110. As such, coupling of the IC 102 to the corresponding pad 108 also couples the IC 102 to such a signal via 110. Thus, a signal may be propagated between the signal via 110 and the IC 102 by way of the signal microvia 150 and the pad 108.

Ground microvias 226 are coupled to the pads 108 surrounding the signal microvias 150 and their corresponding pads 108. For instance, a pair of ground microvias 226 are coupled to each pad 108 surrounding the signal microvias 150. In the illustrated embodiment, for pads 108 positioned along a column 200 having at least one signal microvia 150, the ground microvias 226 are positioned offset from one another along a third axis 228 (e.g., oriented obliquely relative to the first axis 202 and relative to the second axis 206, such as at 45 degrees relative to the first axis 202), whereas for pads 108 positioned at a column 200 that does not include any of the signal microvias 150, the ground microvias 226 are positioned offset from one another along the first axis 202. The ground microvias 226 help isolate electric fields related to the pairs of signal microvias 150. For example, the ground microvias 226 help ground the surrounding pads 108 to block or reduce electric field emission from one of the pairs of signal microvias 150 toward another pair of signal microvias 150. That is, the ground microvias 226 and the corresponding pads 108 block electric field leakage from each pair of signal microvias 150. Thus, interference between electric fields of different pairs of signal microvias 150 may be reduced, thereby maintaining a signal integrity of the respective pairs of signal microvias 150.

The ground microvias 226 may also help isolate the signals at the outer layer 106A (e.g., at the connectors of the IC 102) and the signals at the intermediate layers (e.g., at the signal vias 110) from one another, further helping isolate the signal vias 110 and connectors (e.g., a ball pin field) of the IC 102 from one another. By way of example, the ground microvias 226 may not extend to or be in direct contact with any component of the intermediate layers. The separation between the ground microvias 226 and the components of the intermediate layers may limit contact between components of the outer layer 106A and components of the intermediate layers to help isolate signals directed through the respective components of the outer layer 106A and of the intermediate layers from one another. Accordingly, the ground microvias 226 may limit interference between electric fields at the outer layer 106A, while also discouraging the electric fields at the outer layer 106A from interfering with the electric fields at the intermediate layers. As such, respective signals transmitted by the pads 108 (e.g., at the IC 102) and by the signal vias 110 do not substantially affect one another, thereby further reducing signal loss and improving signal integrity.

Detailed view 230 illustrates positioning of a pair of ground microvias 226 at a third pad 108C (e.g., positioned in a column 200 that does not include any of the signal microvias 150). The ground microvias 226 are offset from one another to form a third dimension 232 extending between the respective centers of the ground microvias 226. For example, each of the ground microvias 226 is positioned at an edge of the pad 108C, and the third dimension 232 is between 0.3 mm and 0.5 mm (between 0.0118 in or 11.8 mil and 0.0197 in or 19.7 mil). Additionally, each of the ground microvias 226 can have a circular shape with a diameter 234 between 0.09 mm and 0.11 mm (between 0.00354 in or 3.54 mil and 0.00433 in or 4.33 mil). However, it should be noted that in additional or alternative embodiments, any suitable quantity of ground microvias 226 (e.g., a single ground microvia 226, more than three ground microvias 226) may be coupled to a corresponding pad 108, and/or the ground microvias 226 may be oriented in any suitable manner relative to one another at a corresponding pad 108.

In certain embodiments, signal vias may be formed through the outer layer 106A, as well as through the intermediate layers. For example, signal vias 236 (e.g., full PTH) are coupled to respective pads 108 (e.g., at positions offset from the centers of the respective pads 108) and through the intermediate layers. The signal vias 236 may extend from one end (e.g., the outer layer 106A) to an opposite end (e.g., another outer layer) of the layers of the PCB 100. Because the signal vias 236 are formed into the corresponding pads 108, in such embodiments, signal microvias 150 are not needed to couple the signal vias 236 to the corresponding pads 108.

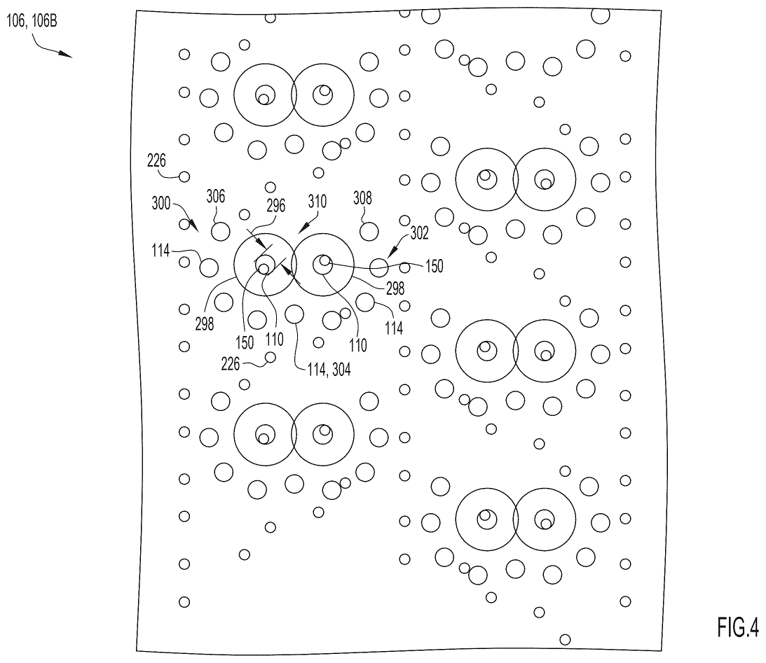

FIG. 4 is a schematic diagram of the intermediate layer 106B (e.g., a ground layer), but the arrangement shown in FIG. 4 may also be applied to any other intermediate layer of the PCB 100. The ground microvias 226 and the signal microvias 150 may extend from the outer layer 106A to the intermediate layer 106B (e.g., to a first side of the intermediate layer 106B). Additionally, the signal vias 110 are formed through the intermediate layer 106B and other intermediate layers of the PCB 100. By way of example, the signal vias 110 extend through the outermost intermediate layer 106B at one end of the PCB 100 to an outermost intermediate layer at an opposite end of the PCB 100. Each signal via 110 may have a circular shape with a diameter 296 that is greater than the diameter 234 of the ground microvias 226. For instance, the diameter 296 may be between 0.15 mm and 0.25 mm (between 0.0059 in or 5.9 mil and 0.00984 in or 9.84 mil). Thus, the signal vias 110 are sufficiently sized to enable the signal microvias 150 extending from the outer layer 106A to overlap with and couple to (e.g., directly contact with) the signal vias 110, such as within the circumference of each signal via 110. An antipad or space 298 is formed around at least some of the signal vias 110 to avoid coupling of the signal vias 110 to the intermediate layer 106B (e.g., to avoid signal transmission along the intermediate layer 106B).

Additionally, the ground vias 114 extend from the intermediate layer 106B (e.g., from a second side, opposite the first side, of the intermediate layer 106B) to isolate the electric fields at each pair of signal vias 110. By way of example, a first plurality of ground vias 300 at least partially surrounds one of a pair of signal vias 110, and a second plurality of ground vias 302 at least partially surrounds the other of the pair of signal vias 110. The first plurality of ground vias 300 and the second plurality of ground vias 302 share a common ground via 304. That is, the common ground via 304 of the ground vias 114 is a part of both the first plurality of ground vias 300 and the second plurality of ground vias 302. For instance, the common ground via 304 is positioned between the pair of signal vias 110. Moreover, the first plurality of ground vias 300 includes a first end ground via 306, and the second plurality of ground vias 302 includes a second end ground via 308. The first end ground via 306 is positioned immediately adjacent to a single other ground via 114 of the first plurality of ground vias 300, and the second end ground via 308 is positioned immediately adjacent to a single other ground via 114 of the second plurality of ground vias 302. As such, a gap 310 is formed between the first end ground via 306 and the second end ground via 308. The gap 310 may enable routing of traces that are connected to the signal vias 110. For instance, the gap 310 provides a sufficient amount of space for traces to be placed at a sufficient distance away from the ground vias 114 to block signal transmission from the traces to the ground vias 114, thereby enabling the ground vias 114 to reduce electric field leakage. Thus, the ground vias 114 are arranged to reduce electric field leakage from the pairs of signal vias 110 while enabling desirable trace routing from the signal vias 110.

The ground vias 114 and the ground microvias 226 may also help form the HDI 152 with the signal microvias 150. Additionally, the ground vias 114 may not extend to or be in direct contact with any component of the outer layer 106A. The separation between the ground vias 114 and the components of the outer layer 106A may limit contact between components of the outer layer 106A and components of the intermediate layers to help isolate signals directed through respective components of the outer layer 106A and of the intermediate layers from one another. By way of example, the ground microvias 226 and the ground vias 114 are separate from one another and may therefore help isolate the electric field contained by the ground microvias 226 at the outer layer 106A from the electric fields contained by the ground vias 114 at the intermediate layer 106B. Accordingly, the ground vias 114 may limit interference between electric fields at the intermediate layer 106B, while also discouraging the electric fields at the intermediate layer 106B from interfering with the electric fields at the outer layer 106A. As such, respective signals transmitted by the pads 108 at the outer layer 106A and by the signal vias 110 at the intermediate layers do not substantially affect one another, thereby reducing signal loss and improving signal integrity. Thus, the HDI 152 may help reduce electric field leakage between the outer layer 106A and the intermediate layer 106B.

Moreover, the HDI 152 may enable greater flexibility related to arrangement of the signal vias 110 and/or of the ground vias 114. As an example, in embodiments that do not include the HDI 152, signal vias and ground vias may be formed through the pads of the outer layer in addition to through the intermediate layers. Therefore, the formation and arrangement of the signal vias and of the ground vias may be more limited to the position of the pads at the outer layer (e.g., the arrangement of the signal vias extending through the intermediate layers is limited to the arrangement of the pads at the outer layer) to communicatively couple the pads to the signal vias and to the ground vias. However, with the HDI 152, the signal microvias 150 are used to communicatively couple the pads 108 and the signal vias 110 to one another. Because the signal vias 110 may be coupled to any suitable part of the signal microvias 150 and the signal microvias 150 may be coupled to any suitable part of the pads 108, there are more positions available for the signal vias 110 (e.g., as compared to having the signal vias 110 be directly coupled to the pads 108 and therefore being more limited to the arrangement of the pads 108) that enable the signal vias 110 to remain coupled to the pads 108 by way of the signal microvias 150. Thus, the signal microvias 150 increase flexibility related to positioning of the signal vias 110 relative to the pads 108. Additionally, because the ground microvias 226 are coupled to the pads 108 to isolate electric fields at the outer layer 106A, the ground vias 114 may be implemented separately and independently from the ground microvias 226 without also having to be coupled to the pads 108 for isolating electric fields at the outer layer 106A. For this reason, the ground vias 114 may be readily positioned at a more suitable location relative to the signal vias 110 to reduce electric field leakage associated with the signal vias 110 at the intermediate layer 106B (e.g., for signals related to a particular data transmission rate and/or a particular wavelength) instead of, for example, being positioned to couple to the pads 108. In other words, the ground vias 114 may be positioned for purposes of isolating the electric fields of the signal vias 110 without being limited by the arrangement of the pads 108. By way of example, the ground vias 114 may be positioned closer to one another and/or to the signal vias 110 as compared to the positioning between the pads 108. As such, the HDI 152 may further help implement a suitable arrangement of the ground vias 114 to reduce electric field leakage.

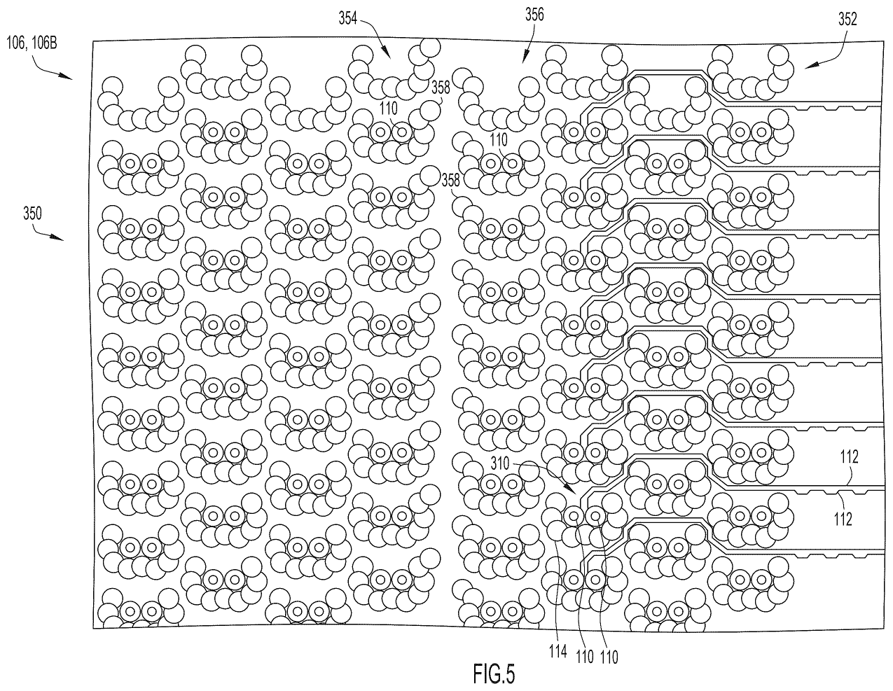

FIG. 5 is a schematic diagram of the intermediate layer 106B, but the arrangement shown in FIG. 5 may also be applied to any other intermediate layer (e.g., another breakout layer) of the PCB 100. The illustrated intermediate layer 106B includes multiple pairs of signal vias 110, as well as the traces 112 coupled to the signal vias 110. For example, the traces 112 extend from the signal vias 110, through the gap 310, and between respective ground vias 114 surrounding different pairs of signal vias 110 (e.g., between the first plurality of ground vias 300 surrounding one of a first pair of signal vias 110 and the second plurality of ground vias 302 surrounding one of a second pair of signal vias 110).

The gap 310 may enable suitable routing of the traces 112. For example, the gap 310 provides a sufficient amount of space for traces 112 of a desirable size, such as between 0.075 mm and 0.1 mm (between 0.003 in or 3 mil and 0.004 in or 4 mil in width), to be implemented and maintain a sufficient distance, such as above 0.1 mm (above 0.003 in or 3 mil), from the ground vias 114. Additionally, the gap 310 may enable the traces 112 to be routed to control and establish signal propagation times. By way of example, a duration of time in which a signal propagates along each trace 112 is based on the respective lengths of the traces 112 (e.g., increasing the length of a trace 112 increases a duration of time in which a signal propagates along the entire length of the trace 112). It may be desirable for the durations in which respective signals propagate along each pair of traces 112 to be approximately equal to one another such that a component can simultaneously receive signals from the pair of traces 112. In other words, it may be desirable to reduce a difference between the durations of time for signals to propagate along different traces 112 of a pair of traces 112 (e.g., to reduce a skew between the pair of traces 112). For this reason, it may also be desirable for the respective lengths of traces 112 of the pair of traces 112 to be approximately equal to one another. To this end, the traces 112 may be routed (e.g., by implementing turns, curves, or bends) to establish approximately equal lengths. The gap 310 may provide a sufficient amount of space to enable such routing of the traces 112.

Additionally or alternatively, the duration of time in which a signal propagates along each trace 112 is based on the material along which the trace 112 extends. For instance, the PCB 100 is composed of a glass weave of different materials, and different portions of each trace 112 may extend along different materials to affect the total duration of time in which a signal propagates along the trace 112. The gap 310 may also provide a sufficient amount of space for the traces 112 to be routed based on the material of the PCB 100 (e.g., such that certain portions of each trace 112 are selectively routed along a particular material) to acutely control the duration of time in which signals propagate along the traces 112, such as to reduce a difference between such durations of time for a pair of traces 112. Indeed, desirable parameters related to the traces 112 (e.g., a size of the traces 112, a distance between the traces 112 and the ground vias 114, a signal propagation time) may be based on different factors, such as a dielectric value and/or an impedance value of the material of the PCB 100. The gap 310 may provide a sufficient amount of space to implement the traces 112 to achieve the desirable parameters. Thus, signal propagation may be better controlled and further improved by the arrangement of the ground vias 114 establishing the gap 310.

The illustrated intermediate layer 106B includes a first array of signal vias 350 and a second array of signal vias 352. For example, the first array of signal vias 350 may be used to transmit signals to a component (e.g., the IC 102), and the second array of signal vias 352 may be used to receive signals from a component (e.g., the IC 102). A first set 354 (e.g., a first column) of the first array of signal vias 350 is adjacent to a second set 356 (e.g., a second column) of the second array of signal vias 352. Thus, signals may propagate in a certain direction with respect to (e.g., toward) each signal via 110 of the first set 354, and signals may propagate in an opposite direction with respect to (e.g., away from) each signal via 110 of the second set 356. The difference in direction of signal propagation between the first set 354 and the second set 356 may cause increased effects (e.g., interference) related to potential electric field leakage between the first set 354 and the second set 356. By way of example, signal transmission from one of the first set 354 or the second set 356 interfering with signal transmission to the other of the first set 354 or the second set 356 produces near-end crosstalk (NEXT).

For this reason, supplemental ground vias 358 may be positioned between the first set 354 and the second set 356 to provide further electric field isolation benefits. As an example, the supplemental ground vias 358 are positioned outside of the first plurality of ground vias 300 and outside of the second plurality of ground vias 302 and therefore do not surround any of the signal vias 110. Thus, the supplemental ground vias 358 may be considered external ground vias. Such arrangement of the supplemental ground vias 358 enables the supplemental ground vias 358 to block electric field leakage from the signal vias 110 of the first set 354 to the signal vias 110 of the second set 356, as well as electric field leakage from the signal vias 110 of the second set 356 to the signal vias 110 of the first set 354, thereby reducing NEXT. As such, the supplemental ground vias 358 further reduce signal loss and improve signal integrity.

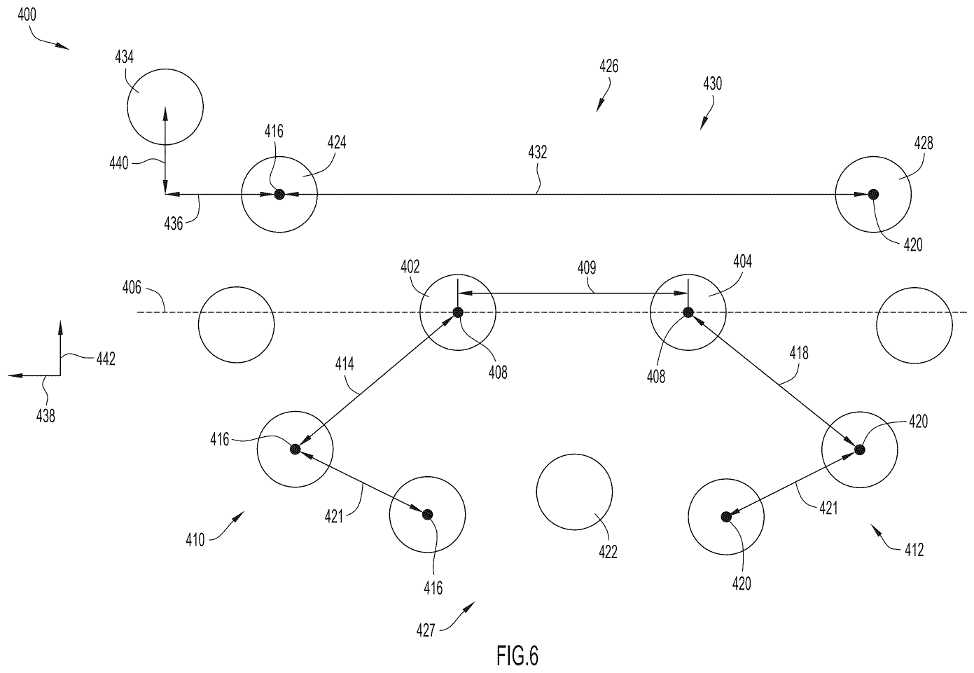

FIG. 6 is a schematic diagram of a via assembly 400, which may be formed at an intermediate layer, such as the intermediate layer 106B, of the PCB 100. For example, the via assembly 400 may be a part of the first set 354 of the first array of signal vias 350 or a part of the second set 356 of the second array of signal vias 352. However, at least some of the descriptions related to the via assembly 400 may be applied to a via assembly positioned at any other part of the intermediate layer or at any other suitable location of the PCB 100. The via assembly 400 includes a first signal via 402 and a second signal via 404 formed through the intermediate layer (e.g., through multiple intermediate layers, terminating prior to an outer layer). The signal vias 402, 404 are positioned such that an axis 406 extends through the respective centers 408 of the signal vias 402, 404. As an example, the signal vias 402, 404 are offset along the axis 406 to provide a first distance 409 extending between the respective centers 408, and the first distance 409 may be between 0.5 mm and 0.8 mm.

Additionally, ground vias are positioned around the signal vias 402, 404 to isolate electric fields of the signal vias 402, 404. For example, a first plurality of ground vias 410 at least partially surrounds the first signal via 402, and a second plurality of ground vias 412 at least partially surrounds the second signal via 404. In some embodiments, the first plurality of ground vias 410 may circumferentially surround the first signal via 402, and/or the second plurality of ground vias 412 may circumferentially surround the second signal via 404. That is, each ground via of the first plurality of ground vias 410 may be positioned at the same distance away from the first signal via 402 to provide a second distance 414 between the center 408 of the first signal via 402 and the center 416 of each of the first plurality of ground vias 410. Additionally or alternatively, each ground via of the second plurality of ground vias 412 may be positioned at the same distance away from the second signal via 404 to provide a third distance 418 between the center 408 of the second signal via 404 and the center 420 of each of the second plurality of ground vias 412. As an example, each of the second distance 414 and the third distance 418 may be between 0.5 mm and 0.8 mm (e.g., the first distance 409, the second distance 414, and the third distance 418 may be approximately equal to one another). In certain embodiments, the first plurality of ground vias 410 and/or the second plurality of ground vias 412 are evenly distributed around the signal vias 402, 404. That is, each of the ground vias of the first plurality of ground vias 410 may be positioned at the same distance or pitch away from an immediately adjacent other ground via of the first plurality of ground vias 410, and/or each of the ground vias of the second plurality of ground vias 412 may be positioned at the same distance or pitch away from an immediately adjacent other ground via of the second plurality of ground vias 412. For instance, a fourth distance 421 extends between the centers 416 of immediately adjacent ground vias of the first plurality of ground vias 410 and/or between the centers 420 of immediately adjacent ground vias of the second plurality of ground vias 412, and the fourth distance 421 may be between 0.3 mm and 0.5 mm.

The first plurality of ground vias 410 and the second plurality of ground vias 412 may include a common ground via 422. The common ground via 422 may be equidistant to the first signal via 402 and to the second signal via 404. Therefore, the common ground via 422 may be positioned between the first signal via 402 and the second signal via 404 along an axis parallel to the axis 406, and the common ground via 422 may be immediately adjacent to both another ground via of the first plurality of ground vias 410 and another ground via of the second plurality of ground vias 412. Additionally, the first plurality of ground vias 410 may include a first ground via 424 (e.g., a first end ground via) positioned at a side 426 of the signal vias 402, 404 (e.g., across the axis 406 from and opposite of a side 427 of the signal vias 402, 404 where the common ground via 422 is positioned), and the second plurality of ground vias 412 may include a second ground via 428 (e.g., a second end ground via) positioned at the same side 426 of the signal vias 402, 404. The first plurality of ground vias 410 may terminate at the first ground via 424 at the side 426, and the second plurality of ground vias 412 may terminate at the second ground via 428 at the side 426. That is, the first ground via 424 is immediately adjacent to a single other ground via of the first plurality of ground vias 410, and the second ground via 428 is immediately adjacent to a single other ground via of the second plurality of ground vias 412. Additionally, as compared to a remainder of the first plurality of ground vias 410 at the side 426, the first ground via 424 is positioned farthest away from the axis 406, and as compared to a remainder of the second plurality of ground vias 412 at the side 426, the second ground via 428 is positioned farthest away from the axis 406. In this manner, the first plurality of ground vias 410 and the second plurality of ground vias 412 may cooperatively form a w-shaped or an o-shaped configuration.

The first ground via 424 and the second ground via 428 are positioned away from one another to form a gap 430 extending between the first ground via 424 and the second ground via 428 at the side 426 of the signal vias 402, 404. The gap 430 is absent of another ground via of the first plurality of ground vias 410 or of the second plurality of ground vias 412. Thus, the gap 430 may provide a sufficient amount of space to enable traces coupled to the signal vias 402, 404 to be routed through the gap 430 and arranged at a sufficient distance away from the ground vias. By way of example, a fifth distance 432 extends between the center 416 of the first ground via 424 and the center 420 of the second ground via 428, and the fifth distance 432 may be between 1 mm and 2 mm. The signal vias 402, 404 may be positioned between the first ground via 424 and the second ground via 428 along an axis parallel to the axis 406.

The via assembly 400 may further include a supplemental ground via 434 to provide additional electric field isolation benefits. For example, the via assembly 400 may be positioned adjacent to another via assembly, and the respective signals propagated along the via assembly 400 and along the other via assembly are transmitted in opposite directions. The supplemental ground via 434 may block interference between electric fields emitted as a result of signal transmission in the opposite directions. The supplemental ground via 434 may be positioned immediately adjacent to the first ground via 424. Therefore, the supplemental ground via 434 is positioned at the side 426 of the signal vias 402, 404. Additionally, the supplemental ground via 434 may be positioned farther away from the signal vias 402, 404. In other words, the supplemental ground via 434 may be positioned outside of the circumferential arrangement of the first plurality of ground vias 410 and of the second plurality of ground vias 412. By way of example, the supplemental ground via 434 may be positioned a first dimension 436 away from the center 416 of the first ground via 424 in a first direction 438 (e.g., parallel to the axis 406) and a second dimension 440 away from the center 416 of the first ground via 424 in a second direction 442, perpendicular to the first direction 438. Each of the first dimension 436 and the second dimension 440 may be between 0.2 mm (0.00787 in or 7.87 mil) and 0.4 mm (0.0157 in or 15.7 mil), and the first dimension 436 may be greater than the second dimension 440. In alternative embodiments, the via assembly 400 may not include the supplemental ground via 434. For instance, in embodiments in which the via assembly 400 is not positioned adjacent to another via assembly configured to transmit signals in an opposite direction, the supplemental ground via 434 may not provide any substantial additional electric field isolation benefits and therefore may not be implemented.

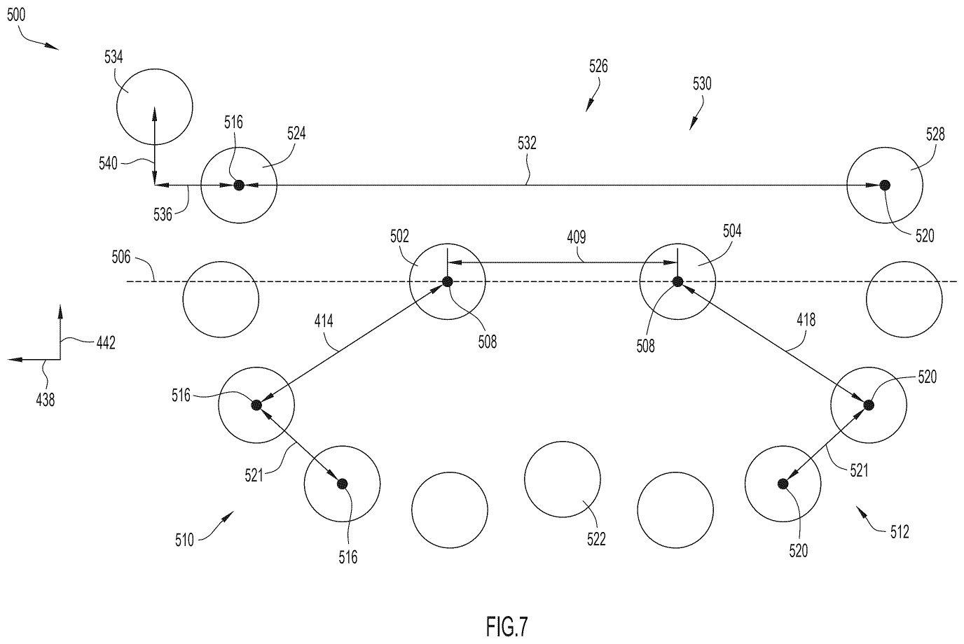

It should be noted that ground vias may be arranged in a different manner with respect to signal vias for another via assembly. For instance, the distribution of ground vias may be adjusted (e.g., by increasing or decreasing the distance between ground vias). A via assembly 500 having a different arrangement of ground vias as compared to that of the via assembly 400 is shown in FIG. 7. The via assembly 500 includes a first signal via 502 and a second signal via 504 positioned such that an axis 506 extends through the respective centers 508 of the signal vias 502, 504. The first distance 409 may extend between the respective centers 508.

A first plurality of ground vias 510 at least partially surrounds (e.g., circumferentially surrounds) the first signal via 502, and a second plurality of ground vias 512 at least partially surrounds (e.g., circumferentially surrounds) the second signal via 504. For instance, the second distance 414 extends between the center 508 of the first signal via 502 and the center 516 of each of the first plurality of ground vias 510, and/or the third distance 418 extends between the center 508 of the second signal via 504 and the center 520 of each of the second plurality of ground vias 512. However, a sixth distance 521 extends between the centers 516 of immediately adjacent ground vias of the first plurality of ground vias 510 and/or between the centers 520 of immediately adjacent ground vias of the second plurality of ground vias 512. The sixth distance 521 is less than the fourth distance 421. As such, the first plurality of ground vias 510 are positioned closer to one another as compared to the first plurality of vias 410, and/or the second plurality of ground vias 512 are positioned closer to one another as compared to the second plurality of ground vias 412. For example, the sixth distance 521 may be between 0.2 mm and 0.4 mm.

The first plurality of ground vias 510 and the second plurality of ground vias 512 may cooperatively form a w-shaped or an o-shaped configuration. To this end, the first plurality of ground vias 510 and the second plurality of ground vias 512 may share a common ground via 522. Additionally, the first plurality of ground vias 510 may terminate at a first ground via 524 positioned at a side 526 of the signal vias 502, 504, and the second plurality of ground vias 512 may terminate at a second ground via 528 positioned at the side 526 of the signal vias 502, 504. Because the first plurality of ground vias 510 are positioned closer to one another, and/or the second plurality of ground vias 512 are positioned closer to one another, a greater quantity of ground vias may be arranged about the signal vias 502, 504. That is, a greater quantity of ground vias may be positioned to surround the signal vias 502, 504, while providing a sufficient amount of space for trace routing. For instance, a gap 530 extends between the first ground via 524 and the second ground via 528 at the side 526 of the signal vias 502, 504, and the first ground via 524 and the second ground via 528 are positioned such that a seventh distance 532 extends between the center 516 of the first ground via 524 and the center 520 of the second ground via 528. The seventh distance 532 may also be between 1 mm and 2 mm, but may be greater than the fifth distance 432 extending between the center 416 of the first ground via 424 and the center 420 of the second ground via 428.

The via assembly 500 may also include a supplemental ground via 534, which may be positioned immediately adjacent to the first ground via 524 at the side 526 of the signal vias 502, 504. The supplemental ground via 534 may be positioned farther away from the signal vias 502, 504 outside of the circumferential arrangement of the first plurality of ground vias 510 and of the second plurality of ground vias 512. For example, the supplemental ground via 534 may be positioned a third dimension 536 away from the center 516 of the first ground via 524 in the first direction 438 (e.g., parallel to the axis 506) and a fourth dimension 540 away from the center 516 of the first ground via 524 in the second direction 442, perpendicular to the first direction 438. The third dimension 536 may be less than the first dimension 436 in which the supplemental ground via 434 is positioned away from the center 416 of the first ground via 424, and the fourth dimension 540 may be less than the second dimension 440 in which the supplemental ground via 434 is positioned away from the center 416 of the first ground via 424. For instance, each of the third dimension 536 and the fourth dimension 540 may be between 0.2 mm (0.00787 in or 7.87 mil) and 0.3 mm (0.0118 in or 11.8 mil), and the third dimension 536 may be greater than the fourth dimension 540. In additional or alternative embodiments, the via assembly 500 may not include the supplemental ground via 534.

It should also be noted that in alternative embodiments, ground vias may be positioned farther away from one another than depicted in FIGS. 6 and 7. In such embodiments, there may be fewer ground vias surrounding the signal vias. In any case, the ground vias may be positioned to provide sufficient isolation of electric fields. For instance, for a high data transmission rate of 224 gigahertz (GHz), the ground vias may be positioned at sufficiently low corresponding distances from one another to shield the data transmission quarter wavelength (e.g., Nyquist frequency) of 56 GHz that is around 0.6 mm. However, it should be noted that the described arrangement of ground vias may also isolate electric fields for data transmission rates that are lower than 224 GHz. That is, the w-shaped or o-shaped configuration of the ground vias may limit crosstalk to improve signal integrity for PCBs having different data transmission rates.

Additionally, although the first plurality of ground vias 410 and the second plurality of ground vias 412 of the via assembly 400 are symmetrical to one another and the first plurality of ground vias 510 and the second plurality of ground vias 512 of the via assembly 500 are symmetrical to one another, respective plurality of ground vias may be positioned asymmetrical to one another in alternative embodiments. Indeed, ground vias may be positioned in any suitable manner to partially surround signal vias.

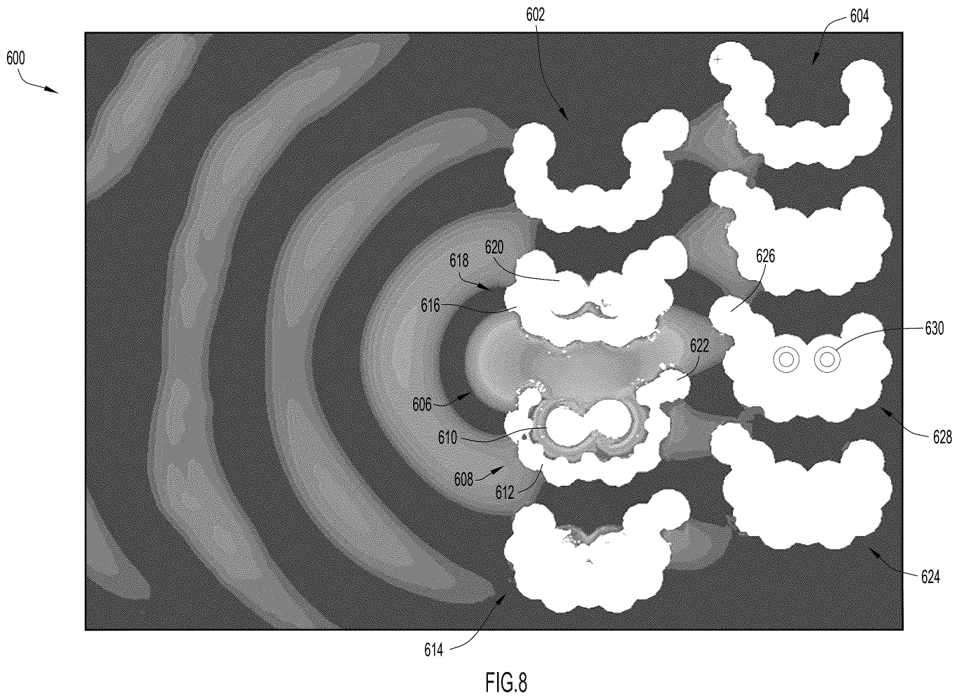

FIG. 8 is a schematic diagram of an intermediate layer 600 (e.g., the intermediate layer 106B) having multiple via assemblies. For example, a first set 602 of via assemblies are used for propagating signals in a first direction, and a second set 604 of via assemblies are used for propagating signals in a second direction, opposite the first direction. Accordingly, the signals propagating in opposite directions for the different sets 602, 604 of via assemblies may interfere with one another by way of overlapping electric fields.

For this reason, each of the via assemblies of the sets 602, 604 of via assemblies includes a supplemental ground via. The supplemental ground via may block an electric field associated with an opposing via assembly from affecting signal propagation. In the illustrated embodiment, an electric field 606 emitted by a first via assembly 608 (e.g., first signal vias 610 of the first via assembly 608) of the first set 602 of via assemblies is shown by way of a heat map. First ground vias 612 of the first via assembly 608 may block or prevent the electric field 606 from being emitted to a second via assembly 614, positioned immediately adjacent to the first via assembly 608, of the first set 602 of via assemblies. Second ground vias 616 of a third via assembly 618, positioned immediately adjacent to the first via assembly 608, of the first set 602 of via assemblies may block or prevent the electric field 606 from being emitted to second signal vias 620 of the third via assembly 618. Moreover, a first supplemental ground via 622 of the first via assembly 608 may block or prevent the electric field 606 from being emitted to a fourth via assembly 624, positioned immediately adjacent to the first via assembly 608, of the second set 604 of via assemblies. A second supplemental ground via 626 of a fifth via assembly 628, positioned immediately adjacent to the first via assembly 608, of the second set 604 of via assemblies may block the electric field 606 from being emitted to third signal vias 630 of the fifth via assembly 628. In this way, the supplemental ground vias 622, 626 may cooperatively block the electric field 606 from being emitted from the first via assembly 608 of the first set 602 of via assemblies to a signal via (e.g., the third signal vias 630) of the second set 604 of via assemblies. Thus, the supplemental ground vias 622, 626 help isolate the electric field 606 to maintain signal integrity related to the second set 604 of via assemblies.

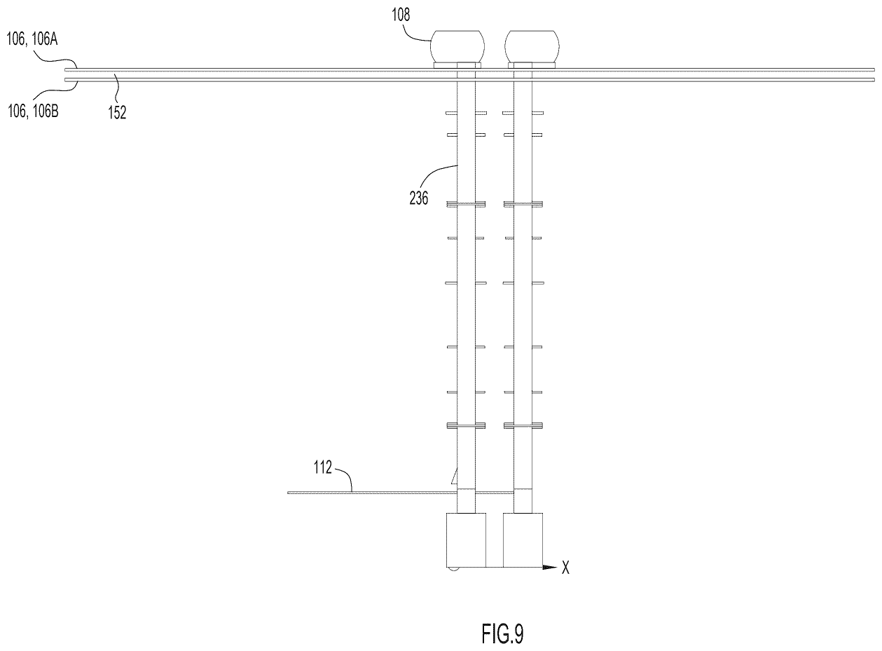

As discussed, a PCB may include the signal vias 236 that are coupled to respective pads 108 and through the intermediate layers. That is, each signal via 236 may extend through the outer layers in addition to the intermediate layers and is not coupled to any signal microvias to couple to the pads 108. FIG. 9 is a side cross-sectional view of the PCB 100 illustrating the signal vias 236. Certain components (e.g., ground vias) are not illustrated for visualization purposes. Each signal via 236 is coupled to a corresponding pad 108 and extends from the pads 108, through the outer layer 106A, and through the intermediate layer 106B, as well as through each other intermediate layer. Thus, each signal via 236 extends through the HDI 152 without usage of a signal microvia (e.g., the signal microvias 150). However, the HDI 152 may nevertheless help isolate a signal transmitted at the outer layer 106A (e.g., at the pads 108) from a signal transmitted at the intermediate layers (e.g., along a portion of the signal vias 236 extending through the intermediate layers) to improve signal integrity associated with the signal vias 236. Respective traces 112 may be coupled to the signal vias 236 at the intermediate layers.

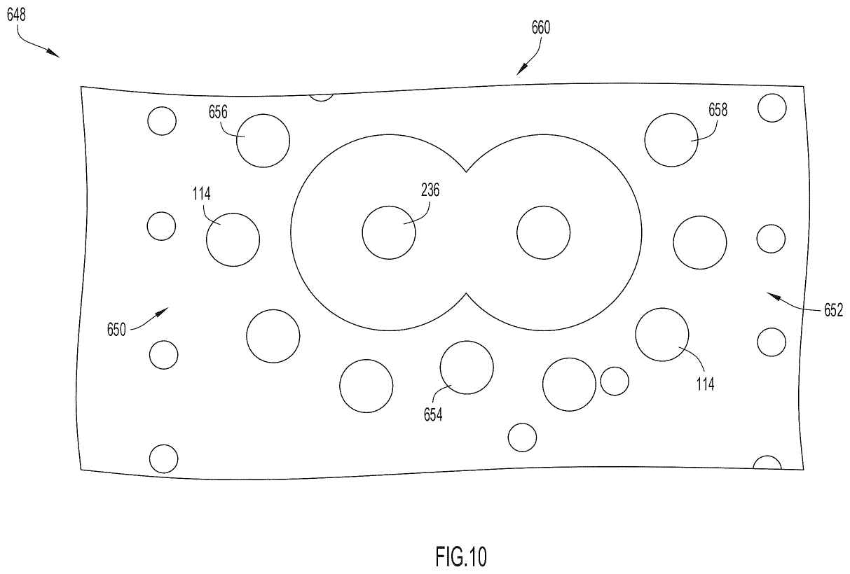

FIG. 10 is a schematic diagram of an intermediate layer (e.g., the intermediate layer 106B) with a via assembly 648 having ground vias 114 surrounding a pair of signal vias 236 that extend from the multiple layers 106 through the intermediate layers. The arrangement of the ground vias 114 is similar to that shown in FIG. 4 in that a first plurality of ground vias 650 at least partially circumferentially surrounds one of the signal vias 236, a second plurality of ground vias 652 at least partially circumferentially surrounds the other of the signal vias 236, and the first plurality of ground vias 650 and the second plurality of ground vias 652 share a common ground via 654. Thus, the first plurality of ground vias 650 and the second plurality of ground vias 652 cooperatively form a w-shaped or an o-shaped configuration around the signal vias 236.

The first plurality of ground vias 650 includes a first end ground via 656 positioned immediately adjacent to a single other ground via 114 of the first plurality of ground vias 650, and the second plurality of ground vias 652 includes a second end ground via 658 positioned immediately adjacent to a single other ground via 114 of the second plurality of ground vias 652. As such, a gap 660 is formed between the first end ground via 656 and the second end ground via 658 to enable routing of traces that are connected to the signal vias 236. Although each of the first plurality of ground vias 650 and the second plurality of ground vias 652 includes five ground vias 114, it should be noted that any suitable quantity of ground vias 114 may surround the signal vias 236 in additional or alternative embodiments. By way of example, the pitch between ground vias 114 may be reduced to position a greater quantity of ground vias 114 around the signal vias 236 (e.g., such that each of the first plurality of ground vias 650 and the second plurality of ground vias 652 includes six ground vias 114). It should also be noted that in some embodiments, a supplemental ground via may be provided to block interference between electric fields associated with the via assembly 648 and another immediately adjacent via assembly for signals transmitted in opposite direction.

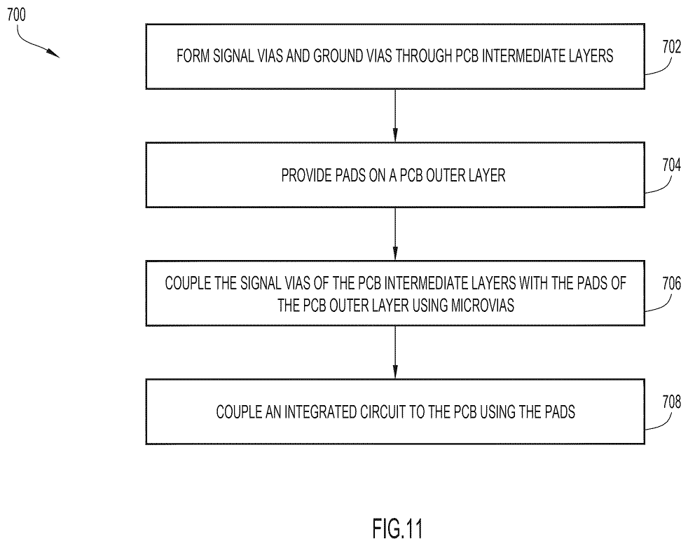

FIG. 11 is a flowchart of a method 700 for manufacturing a PCB, such as the PCB 100. The operations of the method 700 may be performed by a single entity or by multiple entities. It should be noted that the method 700 may be performed differently than depicted. For example, an additional operation may be performed, and/or any of the depicted operations may be performed differently, performed in a different order, and/or not performed.

At step 702, signal vias and ground vias are formed through intermediate layers of the PCB. For example, the ground vias are arranged to cooperatively form a w-shaped or an o-shaped configuration around the signal vias, such as by circumferentially surrounding the signal vias. Such an arrangement of the ground vias may block electric field leakage between the signal vias (e.g., different pairs of signal vias). At least some of the ground vias may include supplemental ground vias that do not surround the signal vias (e.g., are positioned external to the circumferential arrangement of other ground vias), but may nevertheless block some electric field leakage (e.g., electric field leakage between signal vias associated with signal transmission in opposite directions to block crosstalk between signals transmitted in opposite directions).

In some embodiments, at least some of the signal vias and/or some of the ground vias may be plated through hole vias that extend through each of the intermediate layers (e.g., from one outermost intermediate layer to the opposite outermost intermediate layer). In additional or alternative embodiments, at least some of the signal vias and/or some of the ground vias may be blind vias that extend through an outermost intermediate layer, but terminate prior to the opposite outermost intermediate layer (e.g., terminate at an inner intermediate layer), and/or buried vias that do not extend through any of the outermost intermediate layers (e.g., extend through and terminate at inner intermediate layers). For any of these embodiments, the intermediate layers may be laminated to bond and secure the intermediate layers to one another (e.g., to form an intermediate assembly).

At step 704, pads, balls, or pins are provided on an outer layer of the PCB. For example, each pad may be a conductor formed through the outer layer. The pads may be positioned to provide an arrangement (e.g., a pin field, a ball grid array) that may be used to couple to another component, such as using a soldering technique, to communicatively couple the pads to the other component. In certain embodiments, the arrangement of the pads may be preconfigured, such as based on industry standards and/or manufacturing constraints, and may not be easily adjustable.

At step 706, microvias (e.g., signal microvias) may be used to communicatively couple the signal vias of the intermediate layers with the pads of the outer layer. For instance, the signal vias may extend through an outermost intermediate layer and therefore may be exposed at the outermost intermediate layer. Each microvia may be coupled to a respective one of the signal vias exposed at the outermost intermediate layer and to a respective one of the pads at the outer layer, thereby communicatively coupling the signal via and the pad to one another. Thus, the signal vias terminate prior to the outer layer, and the microvias extend between the outer layer and the outermost intermediate layer to couple the outer layer and the intermediate layers (e.g., the intermediate assembly) to one another. For example, the microvias may form an HDI between the outer layer and the outermost intermediate layer.

The usage of the microvias to provide the HDI may enable a more desirable arrangement of the signal vias and of the ground vias, such as to block electric field leakage more suitably. For example, the microvias may increase the available positions of the signal vias that still enable coupling to the pads. Additionally, the HDI may enable the ground vias to be arranged more suitably for blocking electric field leakage in an intermediate layer, such as for a particular data rate transmission and/or signal wavelength (e.g., a quarter wavelength of 56 gigahertz), rather than for direct coupling to the pads to block electric field leakage at the outer layer. Furthermore, the HDI may limit coupling or contact between components of the outer layer and components of the intermediate layers, thereby blocking interference between electric fields at the outer layer and electric fields at the intermediate layers. For this reason, the implementation of the HDI may improve signal integrity as compared to an embodiment in which the HDI is not used (e.g., an embodiment in which signal/ground vias and pads are directly coupled to one another).

In certain embodiments, additional vias may be formed through the PCB after the signal vias of the intermediate layers are communicatively coupled to the pads of the outer layer. By way of example, an additional signal via may be formed through one of the pads of the outer layer and into the intermediate layers. For this reason, the additional signal via may extend through the outer layer and the intermediate layers for signal propagation without usage of a signal microvia (e.g., extending between the outer layer and the outermost intermediate layer). Such an additional signal via may include a plated through hole via that extends from the outer layer and through each of the intermediate layers (e.g., to an opposing outer layer) or a blind via that extends from the outer layer and terminates at an intermediate layer.

At step 708, an IC may be communicatively coupled to the PCB using the pads. By way of example, the pads may remain exposed at the outer layer after coupling to signal vias by way of the microvias. Thus, the pads are accessible for attachment to the IC. Communicatively coupling the IC to the pads may also communicatively couple the IC to the microvias and the signal vias, thereby enabling signal transmission between the IC and the signal vias (e.g., and another component communicatively coupled to the signal vias).

In some embodiments, certain steps of the method 700 may be repeated with respect to an additional outer layer of the PCB. That is, additional pads may be provided on the additional outer layer, the signal vias may also be coupled to the additional pads using additional microvias (e.g., additional signal microvias), and/or another IC may be coupled to the additional pads. For example, the steps of the method 700 may be performed for both a top outer layer and a bottom outer layer of the PCB to provide a belly-to-belly configuration.

In additional or alternative embodiments, back drilling may be performed to reduce extension of at least one of the signal vias. For instance, a bore may be drilled through the outer layer and/or at least one of the intermediate layers to remove a portion of a signal via to reduce conductivity at an end of the signal via that may otherwise reduce signal integrity. Thus, back drilling after forming the signal vias through the intermediate layers may further improve signal transmission. Back drilling of the PCB may create undesirable gaps or spaces in the outer layer and/or the intermediate layers. For this reason, material, such as a sequential dielectric and copper plug, may be implemented to close such gaps and suppress electric field leakage that otherwise may occur as a result of the existing gaps.

The method 700 may also provide additional manufacturing or structural benefits for the PCB. As an example, by limiting extension of the signal vias to terminate prior to the outer layer, the bores drilled through the PCB to accommodate positioning of the signal vias therein may have a sufficiently low aspect ratio, or bore extension (e.g., thickness/length spanning the intermediate layers) divided by drill size (e.g., diameter), such as below 25 to help with signal delivery. As another example, the arrangement of the pads on the outer layer relative to the arrangement of the signal vias at the intermediate layers may facilitate ease of coupling of the pads to the signal vias by way of the microvias (e.g., by avoiding complex offset between the signal vias and pads and/or by avoiding overlap between multiple signal vias per pad), such as using a soldering technique.

In some aspects, the techniques described herein relate to an apparatus including: a layer of a printed circuit board (PCB); a pair of signal vias formed on the layer of the PCB, wherein the pair of signal vias includes a first signal via and a second signal via, each of which is configured to propagate a respective signal; a first plurality of ground vias formed on the layer and at least partially circumferentially surrounding the first signal via of the pair of signal vias; and a second plurality of ground vias formed on the layer and at least partially circumferentially surrounding the second signal via of the pair of signal vias, wherein the first plurality of ground vias and the second plurality of ground vias include a shared ground via.

In some aspects, the techniques described herein relate to an apparatus, including an axis extending through a first center of the first signal via and a second center of the second signal via, wherein the first plurality of ground vias includes a first ground via positioned farthest away from the axis as compared to a remainder of the first plurality of ground vias at a side of the pair of signal vias, the second plurality of ground vias includes a second ground via positioned farthest away from the axis as compared to a remainder of the second plurality of ground vias at the side of the pair of signal vias, and the pair of signal vias are positioned between the first ground via and the second ground via along the axis.

In some aspects, the techniques described herein relate to an apparatus, wherein the first ground via and the second ground via are positioned to form a gap extending between the first ground via and the second ground via at the side of the pair of signal vias, the gap being absent of another ground via of the first plurality of ground vias and another ground via of the second plurality of ground vias.

In some aspects, the techniques described herein relate to an apparatus, further including a trace coupled to one of the pair of signal vias and routed through the gap.

In some aspects, the techniques described herein relate to an apparatus, wherein the first plurality of ground vias and the second plurality of ground vias cooperatively form a w-shaped or o-shaped configuration.

In some aspects, the techniques described herein relate to an apparatus, wherein the shared ground via is positioned between the pair of signal vias.

In some aspects, the techniques described herein relate to an apparatus, further including an axis extending through a first center of the first signal via and a second center of the second signal via, wherein the first plurality of ground vias includes a first ground via positioned farthest away from the axis as compared to a remainder of the first plurality of ground vias at a side of the pair of signal vias, and further including a second ground via positioned adjacent to the first ground via and away from the pair of signal vias.

In some aspects, the techniques described herein relate to an apparatus, further including: an additional layer of the PCB; a pad formed on the additional layer; and a microvia coupled to the pad and to one of the first signal via or the second signal via, wherein the microvia extends between the layer and the additional layer.

In some aspects, the techniques described herein relate to an apparatus, further including an integrated circuit (IC) coupled to the pad.

In some aspects, the techniques described herein relate to an apparatus, further including an additional signal via configured to propagate an additional signal, wherein the additional signal via is formed through the pad and the layer of the PCB.

In some aspects, the techniques described herein relate to an apparatus including: a printed circuit board (PCB) including an intermediate layer and an outer layer; a signal via formed on the intermediate layer; a plurality of ground vias formed on the intermediate layer and at least partially surrounding the signal via; a plurality of pads formed on the outer layer; a signal microvia coupled to a first pad of the plurality of pads and to the signal via; and a plurality of ground microvias, wherein each ground microvia of the plurality of ground microvias is coupled to a respective second pad of the plurality of pads.

In some aspects, the techniques described herein relate to an apparatus, further including an integrated circuit (IC) coupled to the plurality of pads.

In some aspects, the techniques described herein relate to an apparatus, wherein the signal via terminates prior to the outer layer of the PCB.

In some aspects, the techniques described herein relate to an apparatus, wherein each of the signal microvia and the plurality of ground microvias extends between the intermediate layer and the outer layer.

In some aspects, the techniques described herein relate to an apparatus, including an additional signal via formed on the intermediate layer, wherein the plurality of ground vias at least partially surround the additional signal via to form a w-shaped or o-shaped configuration about the signal via and the additional signal via.

In some aspects, the techniques described herein relate to an apparatus, wherein each ground via of the plurality of ground vias is positioned at a first distance away from the signal via, and further including a supplemental ground via, separate from the plurality of ground vias, positioned at a second distance away from the signal via, the second distance being greater than the first distance.

In some aspects, the techniques described herein relate to a method including: forming a signal via extending through a plurality of intermediate layers of a printed circuit board (PCB); forming a plurality of ground vias extending through the plurality of intermediate layers, wherein the plurality of ground vias at least partially circumferentially surrounds the signal via; forming a plurality of pads on an outer layer of the PCB; coupling the signal via to a first pad of the plurality of pads using a signal microvia; and coupling a ground microvia to a second pad of the plurality of pads, wherein the ground microvia extends between the outer layer and an intermediate layer of the plurality of intermediate layers.

In some aspects, the techniques described herein relate to a method, including coupling an integrated circuit to the first pad of the plurality of pads.

In some aspects, the techniques described herein relate to a method, including forming a supplemental ground via, separate from the plurality of ground vias, extending through the plurality of intermediate layers, wherein the supplemental ground via is positioned outside of a circumferential arrangement of the plurality of ground vias around the signal via.

In some aspects, the techniques described herein relate to a method, including: forming an additional signal via extending through the plurality of intermediate layers of the PCB; and forming an additional plurality of ground vias extending through the plurality of intermediate layers, wherein the additional plurality of ground vias at least partially circumferentially surrounds the additional signal via, and the plurality of ground vias and the additional plurality of ground vias cooperatively form a w-shaped or o-shaped configuration.

The above description is intended by way of example only. Although the techniques are illustrated and described herein as embodied in one or more specific examples, it is nevertheless not intended to be limited to the details shown, since various modifications and structural changes may be made within the scope and range of equivalents of the claims.

As used herein, unless expressly stated to the contrary, use of the phrase ‘at least one of’, ‘one or more of’, ‘and/or’, variations thereof, or the like are open-ended expressions that are both conjunctive and disjunctive in operation for any and all possible combination of the associated listed items. For example, each of the expressions ‘at least one of X, Y and Z’, ‘at least one of X, Y or Z’, ‘one or more of X, Y and Z’, ‘one or more of X, Y or Z’ and ‘X, Y and/or Z’ can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Note that in this Specification, references to various features (e.g., elements, structures, nodes, modules, components, engines, logic, steps, operations, functions, characteristics, etc.) included in ‘one embodiment’, ‘example embodiment’, ‘an embodiment’, ‘another embodiment’, ‘certain embodiments’, ‘some embodiments’, ‘various embodiments’, ‘other embodiments’, ‘alternative embodiment’, and the like are intended to mean that any such features are included in one or more embodiments of the present disclosure, but may or may not necessarily be combined in the same embodiments.

Each example embodiment disclosed herein has been included to present one or more different features. However, all disclosed example embodiments are designed to work together as part of a single larger system or method. This disclosure explicitly envisions compound embodiments that combine multiple previously-discussed features in different example embodiments into a single system or method.

Additionally, unless expressly stated to the contrary, the terms ‘first’, ‘second’, ‘third’, etc., are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, ‘first X’ and ‘second X’ are intended to designate two ‘X’ elements that are not necessarily limited by any order, rank, importance, temporal sequence, or hierarchy of the two elements. Further as referred to herein, ‘at least one of’ and ‘one or more of’ can be represented using the ‘(s)’ nomenclature (e.g., one or more element(s)).

As used herein, the terms “approximately,” “generally,” “substantially,” and so forth, are intended to convey that the property value being described may be within a relatively small range of the property value, as those of ordinary skill would understand. For example, when a property value is described as being “approximately” equal to (or, for example, “substantially similar” to) a given value, this is intended to convey that the property value may be within +/−5%, within +/−4%, within +/−3%, within +/−2%, within +/−1%, or even closer, of the given value. Similarly, when a given feature is described as being “substantially parallel” to another feature, “generally perpendicular” to another feature, and so forth, this is intended to convey that the given feature is within +/−5%, within +/−4%, within +/−3%, within +/−2%, within +/−1%, or even closer, to having the described nature, such as being parallel to another feature, being perpendicular to another feature, and so forth. Mathematical terms, such as “parallel” and “perpendicular,” should not be rigidly interpreted in a strict mathematical sense, but should instead be interpreted as one of ordinary skill in the art would interpret such terms. For example, one of ordinary skill in the art would understand that two lines that are substantially parallel to each other are parallel to a substantial degree, but may have minor deviation from exactly parallel.

The techniques presented and claimed herein are referenced and applied to material objects and concrete examples of a practical nature that demonstrably improve the present technical field and, as such, are not abstract, intangible, or purely theoretical. Further, if any claims appended to the end of this specification contain one or more elements designated as “means for [perform]ing [a function] . . . or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

One or more advantages described herein are not meant to suggest that any one of the embodiments described herein necessarily provides all of the described advantages or that all the embodiments of the present disclosure necessarily provide any one of the described advantages. Numerous other changes, substitutions, variations, alterations, and/or modifications may be ascertained to one skilled in the art and it is intended that the present disclosure encompass all such changes, substitutions, variations, alterations, and/or modifications as falling within the scope of the appended claims.

What is claimed is:

1. An apparatus comprising:
a layer of a printed circuit board (PCB);
a pair of signal vias formed on the layer of the PCB, wherein the pair of signal vias comprises a first signal via and a second signal via, each of which is configured to propagate a respective signal;
a first plurality of ground vias formed on the layer and at least partially circumferentially surrounding the first signal via of the pair of signal vias; and
a second plurality of ground vias formed on the layer and at least partially circumferentially surrounding the second signal via of the pair of signal vias, wherein the first plurality of ground vias and the second plurality of ground vias include a shared ground via.

2. The apparatus of claim 1, comprising an axis extending through a first center of the first signal via and a second center of the second signal via, wherein the first plurality of ground vias includes a first ground via positioned farthest away from the axis as compared to a remainder of the first plurality of ground vias at a side of the pair of signal vias, the second plurality of ground vias includes a second ground via positioned farthest away from the axis as compared to a remainder of the second plurality of ground vias at the side of the pair of signal vias, and the pair of signal vias are positioned between the first ground via and the second ground via along the axis.

3. The apparatus of claim 2, wherein the first ground via and the second ground via are positioned to form a gap extending between the first ground via and the second ground via at the side of the pair of signal vias, the gap being absent of another ground via of the first plurality of ground vias and another ground via of the second plurality of ground vias.

4. The apparatus of claim 3, further comprising a trace coupled to one of the pair of signal vias and routed through the gap.

5. The apparatus of claim 1, wherein the first plurality of ground vias and the second plurality of ground vias cooperatively form a w-shaped or o-shaped configuration.

6. The apparatus of claim 1, wherein the shared ground via is positioned between the pair of signal vias.

7. The apparatus of claim 1, further comprising an axis extending through a first center of the first signal via and a second center of the second signal via, wherein the first plurality of ground vias includes a first ground via positioned farthest away from the axis as compared to a remainder of the first plurality of ground vias at a side of the pair of signal vias, and further comprising a second ground via positioned adjacent to the first ground via and away from the pair of signal vias.

8. The apparatus of claim 1, further comprising:
an additional layer of the PCB;
a pad formed on the additional layer; and
a microvia coupled to the pad and to one of the first signal via or the second signal via, wherein the microvia extends between the layer and the additional layer.

9. The apparatus of claim 8, further comprising an integrated circuit (IC) coupled to the pad.

10. The apparatus of claim 8, further comprising an additional signal via configured to propagate an additional signal, wherein the additional signal via is formed through the pad and the layer of the PCB.

11. An apparatus comprising:
a printed circuit board (PCB) comprising an intermediate layer and an outer layer;
a signal via formed on the intermediate layer;
a plurality of ground vias formed on the intermediate layer and at least partially surrounding the signal via;
a plurality of pads formed on the outer layer;
a signal microvia coupled to a first pad of the plurality of pads and to the signal via; and
a plurality of ground microvias, wherein each ground microvia of the plurality of ground microvias is coupled to a respective second pad of the plurality of pads.

12. The apparatus of claim 11, further comprising an integrated circuit (IC) coupled to the plurality of pads.

13. The apparatus of claim 11, wherein the signal via terminates prior to the outer layer of the PCB.

14. The apparatus of claim 11, wherein each of the signal microvia and the plurality of ground microvias extends between the intermediate layer and the outer layer.

15. The apparatus of claim 11, comprising an additional signal via formed on the intermediate layer, wherein the plurality of ground vias at least partially surround the additional signal via to form a w-shaped or o-shaped configuration about the signal via and the additional signal via.

16. The apparatus of claim 11, wherein each ground via of the plurality of ground vias is positioned at a first distance away from the signal via, and further comprising a supplemental ground via, separate from the plurality of ground vias, positioned at a second distance away from the signal via, the second distance being greater than the first distance.

17. A method comprising:
forming a signal via extending through a plurality of intermediate layers of a printed circuit board (PCB);
forming a plurality of ground vias extending through the plurality of intermediate layers, wherein the plurality of ground vias at least partially circumferentially surrounds the signal via;
forming a plurality of pads on an outer layer of the PCB;
coupling the signal via to a first pad of the plurality of pads using a signal microvia; and
coupling a ground microvia to a second pad of the plurality of pads, wherein the ground microvia extends between the outer layer and an intermediate layer of the plurality of intermediate layers.

18. The method of claim 17, comprising coupling an integrated circuit to the first pad of the plurality of pads.

19. The method of claim 17, comprising forming a supplemental ground via, separate from the plurality of ground vias, extending through the plurality of intermediate layers, wherein the supplemental ground via is positioned outside of a circumferential arrangement of the plurality of ground vias around the signal via.

20. The method of claim 17, comprising:
forming an additional signal via extending through the plurality of intermediate layers of the PCB; and
forming an additional plurality of ground vias extending through the plurality of intermediate layers, wherein the additional plurality of ground vias at least partially circumferentially surrounds the additional signal via, and the plurality of ground vias and the additional plurality of ground vias cooperatively form a w-shaped or co-shaped configuration.
